(19) United States
(12) Patent Application Publication
(10) Pub. No.: US 2026/0044162 A1
(43) Pub. Date: Feb. 12, 2026

(54) HEAT DISSIPATION DEVICE

(71) Applicant: Zhejiang Jinko Energy Storage Co., Ltd., Haining (CN)

(72) Inventor: Luhua ZHANG, Haining (CN)

(21) Appl. No.: 19/183,757

(22) Filed: Apr. 18, 2025

(30) Foreign Application Priority Data
Aug. 8, 2024 (CN) 202411087236.3

(51) Int. Cl. G05D 23/19; H05K 7/20

(52) U.S. Cl. CPC G05D 23/1928; H05K 7/20909

(57) ABSTRACT

A heat dissipation device includes: a chamber having at least one shell and configured to receive the high-power driver; a temperature sensor, configured to acquire first detection information and provide the first detection information to a controller; a humidity sensor, configured to acquire second detection information and provide the second detection information to the controller; a pressure sensor, configured to acquire third detection information and provide the third detection information to the controller; a liquid sensor, configured to acquire fourth detection information and provide the fourth detection information to the controller; and the controller, configured to determine whether the chamber is in a predetermined environment based on the first detection information, the second detection information, the third detection information, and the fourth detection information.

### CROSS REFERENCE TO RELATED APPLICATIONS

The present application claims the benefit of priority under the Paris Convention to Chinese Patent Application No. 202411087236.3, filed on Aug. 8, 2024, which is incorporated herein by reference in its entirety.

### TECHNICAL FIELD

Embodiments of the present disclosure relates to the technical field of energy storage, and in particular, relates to a heat dissipation device.

### BACKGROUND

Typically, many high-power drivers that generate a large amount of heat during operation are arranged in an energy storage system. Effective heat dissipation is required to ensure stable operation of these high-power drivers. To meet the corresponding power requirements, many high-power drivers have high ingress protection (IP) ratings.

However, in order to ensure proper heat dissipation, heat dissipation holes are often defined in chambers of the high-power drivers. When an external environment has low humidity, moisture from the air may enter the chambers through these holes, and cause components inside the chambers to become damp and potentially even damaged. To achieve a high IP rating, passive heat dissipation is achieved through heat transfer of the chambers, without active cooling measures. This results in inability to effectively expel produced heat from the chambers. As the heat accumulates, the temperature inside the chambers rises, leading to unstable operation or damage of the components inside the chambers.

### SUMMARY

Embodiments of the present disclosure provide a heat dissipation device, which at least facilitates heat dissipation of the chamber and ensures a higher IP protection rating for the chamber.

According to one aspect of the embodiments of the present disclosure, a heat dissipation device applicable to a high-power driver is provided. The heat dissipation device includes: a controller; a chamber formed by a housing, where the housing comprises at least one shell operable to be opened to allow air convection between an interior and an exterior of the chamber, and wherein the chamber is configured to receive the high-power driver and is waterproof and dustproof, the high-power driver including an inverter or a converter; a temperature sensor, configured to detect a temperature difference between the interior and the exterior of the chamber, and to provide first detection information to the controller based on detected temperature difference; a humidity sensor, configured to detect a humidity outside the chamber, and to provide second detection information to the controller based on detected humility difference; a pressure sensor, configured to detect a pressure applied by an external environment on the chamber, and to provide third detection information to the controller based on detected pressure; a liquid sensor, configured to detect a height of a liquid outside the chamber with reference to a bottom surface of the chamber, and to provide fourth detection information to the controller based on detected height of the liquid; where the controller is configured to receive the first detection information, the second detection information, the third detection information, and the fourth detection information, and to determine whether the chamber is in a predetermined environment based on the first detection information, the second detection information, the third detection information, and the fourth detection information; where, in response to determining that the chamber is in the predetermined environment, the controller is configured to cause the shell to open; and in in response to determining that the chamber is not in the predetermined environment, the controller is configured to cause the shell to close such that the chamber is sealed.

In some embodiments, determining whether the chamber is in the predetermined environment based on the first detection information, the second detection information, the third detection information, and the fourth detection information includes: determining, based on the first detection information, whether the chamber satisfies a first predetermined condition, determining, based on the second detection information, whether the chamber satisfies a second predetermined condition, determining, based on the third detection information, whether the chamber satisfies a third predetermined condition, and determining, based on the fourth detection information, whether the chamber satisfies a fourth predetermined condition. In response to determining that the chamber simultaneously satisfies the first predetermined condition, the second predetermined condition, the third predetermined condition, and the fourth predetermined condition, determining that the chamber is in the predetermined environment; and in response to determining that the chamber does not satisfy at least one of the first predetermined condition, the second predetermined condition, the third predetermined condition, or the fourth predetermined condition, determining that the chamber is not in the predetermined environment. The first predetermined condition is that the temperature difference between the interior and the exterior of the chamber is greater than or equal to a first predetermined value. The second predetermined condition is that the humidity outside the chamber is less than a second predetermined value. The third predetermined condition is that the external pressure applied by an external environment on the chamber is less than a third predetermined value. The fourth predetermined condition is that the height of liquid outside the chamber is lower than the bottom surface of the chamber.

In some embodiments, the first predetermined value ranges from 20° C. to 40° C.; and/or, the second predetermined value ranges from 70% to 80%; and/or, the third predetermined value ranges from 0.8 MPa to 1.2 MPa.

In some embodiments, the heat dissipation device further includes: a heat dissipation unit, arranged inside the chamber. The controller is further configured to, in a case where the shell is controlled to open based on the first detection information, the second detection information, the third detection information, and the fourth detection information, activate the heat dissipation unit, such that the heat dissipation unit is in an operating state.

In some embodiments, the chamber further includes at least one heat generation unit, and the heat dissipation unit is disposed in a portion of the chamber close to the heat generation unit.

In some embodiments, the heat dissipation unit includes at least one pair of fans, where the pair of fans includes an intake fan and an exhaust fan.

In some embodiments, an overall exterior surface area of the housing is a first area, and an exterior surface area of the shell is a second area, a ratio of the second area to the first area ranging from 20% to 40%.

In some embodiments, the housing includes at least two shells spaced apart, and the predetermined environment includes a first-level predetermined environment and a second-level predetermined environment; and the controller is further configured to: in a case where it is determined based on the first detection information, the second detection information, the third detection information, and the fourth detection information that the chamber is in the first-level predetermined environment, control N shells to open; or in a case where it is determined based on the first detection information, the second detection information, the third detection information, and the fourth detection information that the chamber is in the second-level predetermined environment, control more than N shells to open, where N is a positive integer greater than or equal to 1.

In some embodiments, the heat dissipation device further includes: a smoke sensor, configured to detect smoke in an external environment outside the chamber, and provide a detection result as fifth detection information to the controller. The controller is further configured to determine, based on the fifth detection information, whether smoke is present outside the chamber. In response to determining that smoke is present outside the chamber, the controller controls the shell to close; and in response to determining that smoke is not present outside the chamber, the controller determines whether the chamber is in the predetermined environment based on the first detection information, the second detection information, the third detection information, and the fourth detection information.

In some embodiments, the heat dissipation device further includes: a camera, configured to capture an image of an external environment outside the chamber, and provide an imaging result as sixth detection information to the controller. The controller is further configured to determine, based on the sixth detection information, whether a living organism is present outside the chamber. In response to determining that a living organism is present outside the chamber, the controller controls the shell to close; and in response to determining that no living organism is present outside the chamber, the controller determines whether the chamber is in the predetermined environment based on the first detection information, the second detection information, the third detection information, and the fourth detection information.

The technical solutions according to the embodiments of the present disclosure may achieve the following beneficial effects:

An shell is designed on a housing of a chamber, and additionally, a temperature sensor, a humidity sensor, a pressure sensor, and a liquid sensor are incorporated to comprehensively monitor an environment of the chamber from at least four aspects. Furthermore, a controller is then designed to comprehensively consider various detection information data from these sensors to determine whether the chamber is in a predetermined environment. Based on coordination of the temperature sensor, the humidity sensor, the pressure sensor, the liquid sensor, and the controller, the controller may control the shell to open only in a case where the chamber is in the predetermined environment. This allows the chamber to achieve rapid heat dissipation through inside-outside air convection via the shell. Furthermore, in a case where the chamber is not in the predetermined environment, the controller controls the shell to close. This ensures that the chamber remains in a sealed state to maintain a high IP protection rating. It is noteworthy that in a case where the chamber is in the predetermined environment, it is understood that there is no moisture or other contaminants in the environment that could damage the components inside the chamber. This ensures that when the shell is opened, the components inside the chamber may not be damaged by exposure to the external environment.

### BRIEF DESCRIPTION OF THE DRAWINGS

One or more embodiments are illustrated by way of example, and not by limitation, in the accompanying drawings, where components having the same reference numeral designations represent like components throughout. The drawings are not to scale, unless otherwise disclosed. For clearer descriptions of the technical solutions in the embodiments of the present disclosure or in the related art, drawings that are to be referred for description of the embodiments are briefly described hereinafter. Apparently, the drawings described hereinafter merely illustrate some embodiments of the present disclosure. Persons of ordinary skill in the art may also derive other drawings based on the drawings described herein without any creative effort.

FIG. 1 is a schematic diagram of a simplified structure of a heat dissipation device according to some embodiments of the present disclosure;

FIG. 2 is a schematic partial top view of a heat dissipation device according to some embodiments of the present disclosure;

FIG. 3 is a schematic partial cross-sectional view of a chamber in a heat dissipation device according to some embodiments of the present disclosure;

FIG. 4 is a functional block diagram of a heat dissipation device according to some embodiments of the present disclosure;

FIG. 5 is a schematic partial cross-sectional view of a heat dissipation device according to some embodiments of the present disclosure;

FIG. 6 is another schematic partial cross-sectional view of a heat dissipation device according to some embodiments of the present disclosure;

FIG. 7 is a side view of a chamber in a heat dissipation device according to some embodiments of the present disclosure; and

FIG. 8 is another functional block diagram of a heat dissipation device according to some embodiments of the present disclosure;

### DETAILED DESCRIPTION

It is known from the background that it is difficult to balance effective heat dissipation of a chamber of a high-power driver and a high IP protection rating.

Embodiments of the present disclosure provide a heat dissipation device, where an shell is designed on a housing of a chamber, and additionally, a temperature sensor, a humidity sensor, a pressure sensor, and a liquid sensor are incorporated to comprehensively monitor an environment of the chamber from at least four aspects. Furthermore, a controller is then designed to comprehensively consider various detection information data from these sensors to determine whether the chamber is in a predetermined environment. Based on coordination of the temperature sensor, the humidity sensor, the pressure sensor, the liquid sensor, and the controller, the controller may control the shell to open only in a case where the chamber is in the predetermined environment. This allows the chamber to achieve rapid heat dissipation through inside-outside air convection via the shell. Furthermore, in a case where the chamber is not in the predetermined environment, the controller controls the shell to close. This ensures that the chamber remains in a sealed state to maintain a high IP protection rating. It is noteworthy that in a case where the chamber is in the predetermined environment, it is understood that there is no moisture or other contaminants in the environment that could damage the components inside the chamber. This ensures that when the shell is opened, the components inside the chamber may not be damaged by exposure to the external environment.

In the description of the present disclosure, the terms “first,” “second,” and the like are only used for distinguishing different objects, but shall not be understood as indication or implication of relative importance or implicit indication of the number of the specific technical features, the specific sequence or priorities. In the description of the embodiments of the present disclosure, the term “multiple” or “a plurality of” signifies at least two, unless otherwise specified.

The terms “example” and “embodiment” in this specification signify that the specific characteristic, structures or features described with reference to the embodiments may be covered in at least one embodiment of the present disclosure. This term, when appearing in various parts of the specification, neither indicates the same embodiment, nor indicates an independent or optional embodiment that is exclusive of the other embodiments. A person skilled in the art would implicitly or explicitly understand that the embodiments described in this specification may be incorporated with other embodiments.

In the description of the embodiments of the present disclosure, the term “and/or” is merely an association relationship for describing associated objects, which represents that there may exist three types of relationships. For example, the phrase “A and/or B” may indicate (A), (B), or (A and B). In addition, the forward-slash symbol “/” generally represents an “or” relationship between associated objects before and after the symbol.

In the description of the embodiments of the present disclosure, the term “multiple” or “a plurality of” signifies more than two (including two), unless otherwise specified. Likewise, the term “a plurality of groups” or “multiple groups” signifies more than two groups (including two groups), and the term “a plurality of pieces” or “multiple pieces” signifies more than two pieces (including two pieces).

In the description of the embodiments of the present disclosure, it should be understood that the terms “central,” “transversal,” “longitudinal,” “length,” “width,” “thickness,” “upper,” “lower,” “front,” “rear,” “left,” “right,” “vertical,” “horizontal,” “top,” “bottom,” “inner,” “outer,” “clockwise,” “counterclockwise,” “axial,” “radial,” “circumferential,” and the like indicate orientations and position relationships which are based on the illustrations in the accompanying drawings, and these terms are merely for ease and brevity of the description, instead of indicating or implying that the devices or elements shall have a particular orientation and shall be structured and operated based on the particular orientation. Accordingly, these terms shall not be construed as limiting the present disclosure.

In the description of the embodiments of the present disclosure, it should be noted that unless otherwise specified and defined, the terms “mounted,” “coupled,” “connected,” “secured,” and derivative forms thereof shall be understood in a broad sense, which, for example, may be understood as secured connection, detachable connection or integral connection; may be understood as mechanical connection or electrical connection, or understood as direct connection, indirect connection via an intermediate medium, or communication between the interiors of two elements or interactions between two elements. Persons of ordinary skill in the art may understand the specific meanings of the above terms in the embodiments of the present disclosure according to the actual circumstances and contexts.

In the accompanying drawings of the embodiments of this disclosure, the thickness and area of layers have been magnified for better understanding and convenience of description. When describing one member or component (for example, a layer, a thin film, a portion, or a substrate) as being on or on a surface of another member or component, the member or component may be “directly” disposed on the surface of the another member or component, or there may be a third member or component between the two members or components. Conversely, when describing one member or component as being on a surface of another member or component, or when another member or component is formed or arranged on a surface of one member or component, it means that no third component is present between these two members or components. Furthermore, when describing one member or component as being “substantially” formed on another member or component, it means that the member or component is neither formed on an entire surface (or front surface) of the other member or component, nor formed on an entire edge of the surface.

In the description of the embodiments of the present disclosure, where one member or component “includes” another member or component, unless otherwise specified, it does not exclude other members or components, and additional members or components may also be included. In addition, when a member or component such as a layer, a film, a portion, or a plate is described as being “on/disposed on” another member or component, they may be “directly on” the other member or component (i.e., located on the surface of the other member or component with no other members or components in between), or there may be another member or component present in between them. Furthermore, when a layer, film, portion, plate, or other member or component is described as being “directly on” another member or component, or when a layer, film, portion, or plate is disposed on the surface of another member or component, it means that no other members or components is positioned between them.

The terminology used in the description of various embodiments herein is intended to describe specific embodiments and is not intended to construe any limitation. As used in the descriptions of the various embodiments and the appended claims, the term “member” is also intended to include the plural form, unless explicitly indicated otherwise by the context. The member includes a layer, a film, a portion, or a plate.

The embodiments of the present disclosure are described in detail with reference to the accompanying drawings. However, persons of ordinary skill in the art may understand, in the embodiments of the present disclosure, more technical details are provided for readers to better understand the embodiments of the present disclosure. However, even though these technical details and various variations and modifications based on the embodiments hereinafter, the technical solutions according to the embodiments of the present disclosure may also be practiced.

Some embodiments of the present disclosure provide a heat dissipation device. The heat dissipation device according to the embodiments of the present disclosure is described in detail with reference to the accompanying drawings.

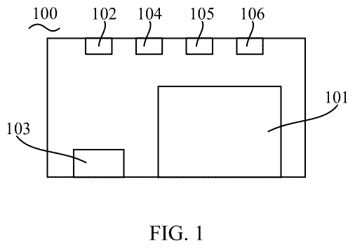

Referring to FIG. 1 to FIG. 3, a heat dissipation device 100 is applicable to a high-power driver. The heat dissipation device 100 includes: a controller 103; a chamber 101 formed by a housing 111. The housing 111 comprises at least one shell 121 operable to be opened to allow air convection between an interior and an exterior of the chamber 101. The chamber 101 is configured to receive the high-power driver and is waterproof and dustproof, the high-power driver including an inverter or a converter. The heat dissipation device 100 further includes a temperature sensor 102, configured to detect a temperature difference between the interior and the exterior of the chamber, and to provide first detection information test 1 to the controller 103 based on detected temperature difference. The heat dissipation device 100 further includes a humidity sensor 104, configured to detect a humidity outside the chamber 101, and to provide second detection information test2 to the controller 103based on detected humility difference. The heat dissipation device 100 further includes a pressure sensor 105, configured to detect a pressure applied by an external environment on the chamber 101, and to provide third detection information test3 to the controller 103 based on detected pressure. The heat dissipation device 100 further includes a liquid sensor 106, configured to detect a height of a liquid outside the chamber 101 with reference to a bottom surface of the chamber 101, and to provide fourth detection information test4 to the controller 103 based on detected height of the liquid. The controller 103 is configured to receive the first detection information test1, the second detection information test2, the third detection information test3, and the fourth detection information test4, and to determine whether the chamber 101 is in a predetermined environment based on the first detection information test1, the second detection information test2, the third detection information test3, and the fourth detection information test4. In response to determining that the chamber 101 is in the predetermined environment, the controller 103 is configured to cause the shell 121 to open; and in response to determining that the chamber 101 is not in the predetermined environment, the controller 103 is configured to cause the shell 121 to close such that the chamber 101 is sealed.

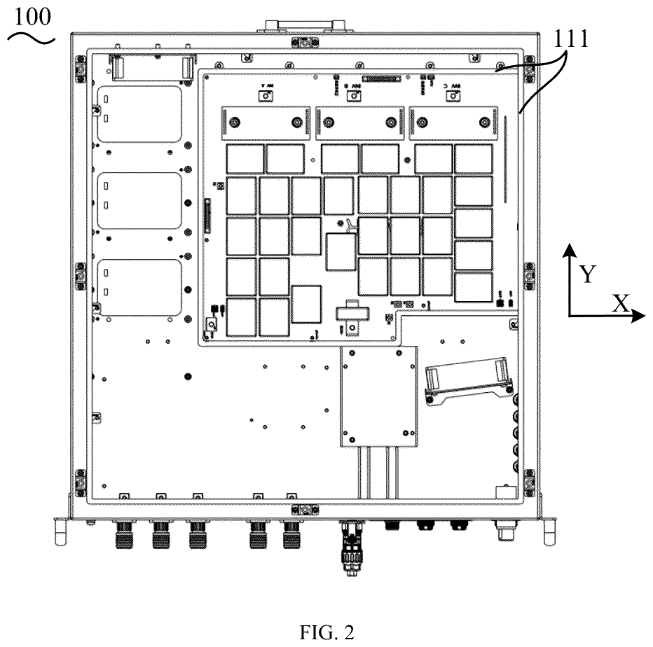

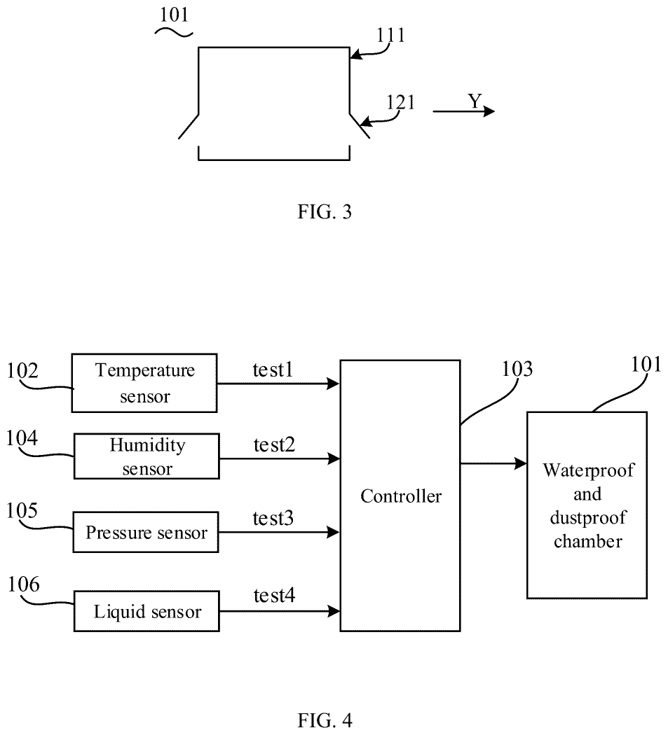

It should be noted that FIG. 1 is a schematic diagram of a simplified structure of a heat dissipation device according to some embodiments of the present disclosure, FIG. 2 is a schematic partial top view of a heat dissipation device according to some embodiments of the present disclosure and FIG. 3 is a schematic partial cross-sectional view of a chamber in a heat dissipation device according to some embodiments of the present disclosure. In addition, for illustration of the components included in the heat dissipation device 100, different rectangles are used to represent the chamber 101, the temperature sensor 102, the humidity sensor 104, the pressure sensor 105, the liquid sensor 106, and the controller 103. In practice, for accommodation of mounting requirements of the other components in the heat dissipation device 100, adjustment of testing orientations of the temperature sensor 102, the humidity sensor 104, the pressure sensor 105, and the liquid sensor 106, or adjustment of a distance between the controller 103 and the chamber 101, positional relationships of the temperature sensor 102, the humidity sensor 104, the pressure sensor 105, the liquid sensor 106, and the controller 103 relative to the chamber 101 may be adjusted, as exemplarily illustrated in FIG. 1. FIG. 2 schematically illustrates an internal structure of the heat dissipation device 100 and the chamber 101, with top surfaces of the heat dissipation device 100 and the chamber 101 not illustrated. The chamber 101 includes a number of components, which are not elaborated herein. In addition to the chamber 101, the heat dissipation device 100 further includes other components, which are not discussed herein.

It is noteworthy that, in order to ensure that the chamber 101 has a high IP protection rating and is not affected by external factors such as water or dust, the timing for opening the shell 121 on the housing 111 of the chamber 101 is quite strict. The shell 121 may not be opened once a specific condition is satisfied; instead, the shell 121 may be opened only when the controller 103 determines that the above four types of detection information all sassies their respective conditions, such that the chamber 101 is communicated with the external environment, thereby enabling inside-outside air convection to rapidly dissipate heat and cool the interior of the chamber 101, and thus preventing heat accumulation inside the chamber 101. This helps to avoid excessive temperature rise, which may lead to instability or damage to the components within the chamber 101. In other words, in the heat dissipation device according to the embodiments of the present disclosure, based on comprehensive judgment on the environment surrounding the chamber 101 by the controller 103, during rapid heat dissipation from the chamber 101, the components inside the chamber 101 may be effectively protected from damage by water vapor or other debris. At other times, the controller 103 may control the chamber 101 to remain in a sealed state, thereby ensuring a high IP protection rating for the chamber 101.

In some examples, the IP protection rating for the chamber 101 may be IP65 or higher. Specifically, an IP protection rating of IP65 means complete protection against the ingress of foreign objects and dust, as well as resistance to low-pressure water jets from any angle.

Specifically, the controller 103 needs to determine, based on the first detection information test1 acquired by the temperature sensor 102, whether the temperature inside the chamber 101 is too high to determine whether quick heat dissipation is required. In response to determining that the temperature difference between the interior and the exterior of the chamber 101 is not significant, and the temperature inside the chamber 101 is not high, the controller 103 controls the shell 121 to close, such that the chamber 101 is in a sealed state to maintain a high IP protection rating, and heat dissipation is achieved by heat transfer of the chamber 101. Furthermore, in a case where the controller 103 determines, based on the first detection information test1, that the temperature inside the chamber 101 is too high, the controller 103 needs to further determine, based on the second detection information test2, the third detection information test3, and the fourth detection information test4, whether a humidity outside the chamber 101, a pressure applied by an external environment on the chamber 101, and a height of liquid outside the chamber 101 all satisfy expected criteria.

Based on this, while determining that the temperature difference between the interior and the exterior of the chamber 101 is high, the controller 103 may control the shell 121 to open only in response to determining that the humidity, the pressure, and the height of liquid outside the 101 all satisfy the expected criteria. This effectively ensures that the elements or components inside the chamber 101 are not damaged by water vapor or other debris. In other words, even when the shell 121 is opened, the chamber 101 is in a preset environment, and thus a high protection rating is maintained for the chamber 101. Therefore, in the heat dissipation device 10 according to the embodiments of the present disclosure, cooperation between the temperature sensor 102, the humidity sensor 104, the pressure sensor 105, the liquid sensor 106, the controller 103, and the shell 121 facilitates heat dissipation of the chamber 101, while further ensuring a high IP protection rating for the chamber 101.

The embodiments of the present disclosure are described in detail hereinafter with reference to the accompanying drawings.

In some embodiments, referring to FIG. 4, FIG. 4 is a functional block diagram of a heat dissipation device according to some embodiments of the present disclosure. Determining, by the controller 103 based on the first detection information test1, the second detection information test2, the third detection information test3, the fourth detection information test4, whether the chamber 101 is in the predetermined environment includes: determining, based on the first detection information test1, whether the chamber 101 satisfies a first predetermined condition, determining, based on the second detection information test2, whether the chamber 101 satisfies a second predetermined condition, determining, based on the third detection information test3, whether the chamber 101 satisfies a third predetermined condition, determining, based on the fourth test information test4, whether the chamber 101 satisfies a fourth predetermined condition; determining that the chamber 101 is in the predetermined environment in response to determining that the chamber 101 simultaneously satisfies the first predetermined condition, the second predetermined condition, the third predetermined condition, the fourth predetermined condition, and the fourth predetermined condition; and determining that the chamber 101 is not in the predetermined environment in response to determining that the chamber 101 does not satisfy at least one of the first predetermined condition, the second predetermined condition, the third predetermined condition, or the fourth predetermined condition.

The first predetermined condition is that the temperature difference between the interior and the exterior of the chamber 101 is greater than or equal to a first predetermined value, the second predetermined condition is that the humidity outside the chamber 101 is less than a second predetermined value, the third predetermined condition is that the pressure applied by the external environment on the chamber 101 is less than a third predetermined value, and the fourth predetermined condition is that the height of liquid outside the chamber 101 is lower than the bottom surface of the chamber 101.

It is noteworthy that: First, the controller 103 determines whether the temperature difference between the interior and the exterior of the chamber 101 is greater than or equal the first predetermined value, i.e., whether a large amount of heat is accumulated inside the chamber 101 and whether effective heat dissipation may be achieved for the chamber 101 via heat transfer thereof. This prevents frequent opening of the shell 121 and avoids prolonged exposure of the components or elements inside the chamber 101 to the external environment, thereby maintaining the IP protection rating for the chamber 101.

Second, the controller 103 determines whether the humidity outside the chamber 101 is less than the second predetermined value, i.e., whether the humidity outside the chamber 101 is excessively high. An excessive high humidity outside the chamber 101 results in a high concentration of water vapor in the ambient air. Under such conditions, opening the shell 121 may lead to condensation inside the chamber 101. Where electronic components or elements are arranged within the chamber 101, a high content of water vapor in the external environment may cause dielectric breakdown in circuits of these components, and hence cause circuit failures. Therefore, by determining whether the humidity outside the chamber 101 is lower than the second predetermined value, the controller 103 effectively prevents condensation inside the chamber 101 and mitigates the risk of circuit failures when the shell 121 is opened.

Third, the controller 103 determines whether the pressure applied by the external environment on the chamber 101 is less than the third predetermined value, i.e., whether the pressure applied by the external environment on the chamber 101 is excessively great. Where the pressure applied by the external environment on the chamber 101 is excessively great, it is determined that the external environment of the chamber 101 is harsh. For example, the high temperature in the external environment may cause an increase in air pressure, or foreign objects may fall onto the chamber 101, applying a large force thereto, or fire or other unstable factors are present in the external environment. Therefore, in response to determining that the pressure applied by the external environment on the chamber 101 is not less than the third predetermined value, it may be concluded that it is not suitable to open the shell 121. The housing 111 helps to isolate the components or elements inside the chamber 101 from the harsh external environment, such that the components or elements are prevented from being affected by the harsh external environment outside the chamber 101.

Fourth, the controller 103 determines whether the height of liquid outside the chamber 101 is lower than the bottom surface of the chamber 101, i.e., whether, when the shell 121 is opened, liquid outside the chamber 101 may invade into the chamber 101. This helps to ensure that, after the shell 121 is opened, the components or elements inside the chamber 101 are not affected by the liquid outside the chamber 101.

In summary, the controller 103 evaluates the environment of the chamber 101 from four aspects: the temperature difference between the interior and the exterior of the chamber 101, the humidity outside the chamber 101, the pressure applied by the external environment on the chamber 101, and the height of liquid outside the chamber 101. Based on these factors, the controller determines whether the shell 121 is to be opened. This ensures a high IP protection rating for the chamber 101, such as IP65 or higher, while achieving heat dissipation for the chamber 101.

It should be noted that any chamber with a high requirement on the IP protection rating may be considered as the chamber 101 according to the embodiments of the present disclosure. The embodiments of the present disclosure do not limit the specific components or elements of the chamber 101. For example, chambers used in high-power drivers with an IP protection rating of IP65 or higher may all apply the chamber 101 according to the present disclosure. Depending on the specific components or elements inside the chamber 101, the first predetermined value, the second predetermined value, and the third predetermined value designed in the controller 103 may all be adjusted flexibly to better satisfy heat dissipation requirements and IP protection rating requirements of the relevant components or elements.

Hereinafter, magnitudes of the first predetermined value, the second predetermined value, and the third predetermined value are described in detail by an example where the high-power driver is an inverter or a converter.

In some examples, the first predetermined value may range from 20° C. to 40° C. For example, the first predetermined value may be 21° C., 22° C., 23° C., 24° C., 25° C., 26° C., 27° C., 28° C., 29° C., 30° C., 31° C., 32° C., 33° C., 34° C., 35° C., 36° C., 37° C., 38° C., or 39° C.

In some examples, the second predetermined value may range from 70% to 80%. For example, the second predetermined value may be 71%, 72%, 73%, 74%, 75%, 76%, 77%, 78%, or 79%.

In some examples, the third predetermined value may range from 0.8 MPa to 1.2 MPa. For example, the third predetermined value may be 0.85 MPa, 0.9 MPa, 0.95 MPa, 1 MPa, 1.05 MPa, 1.1 MPa, or 1.15 MPa.

It is noteworthy that for chambers 101 with different IP protection ratings, the heat dissipation device 100 according to the embodiments of the present disclosure may be used to achieve effective heat dissipation for the chambers while ensuring that the chambers maintain the corresponding IP protection ratings. The control logic in the controller 103 for determining whether the shell 121 is to be opened is similar across different protection ratings.

In some cases, the controller 103 may also be configured such that, in a case where the third detection information (test3) indicates that the chamber 101 does not satisfy the third predetermined condition, i.e., it is determined that the external environment of the chamber is harsh, the components or elements inside the chamber 101 are controlled to be in a turned-off state. In other words, in a case where the controller 103 determines that the external environment of the chamber 101 is harsh, the controller 103 may control the components or elements inside the chamber 101 to stop operating. This further prevents damage to the components or elements during operation, and avoids the high temperature caused by the components or elements operating inside the chamber 101.

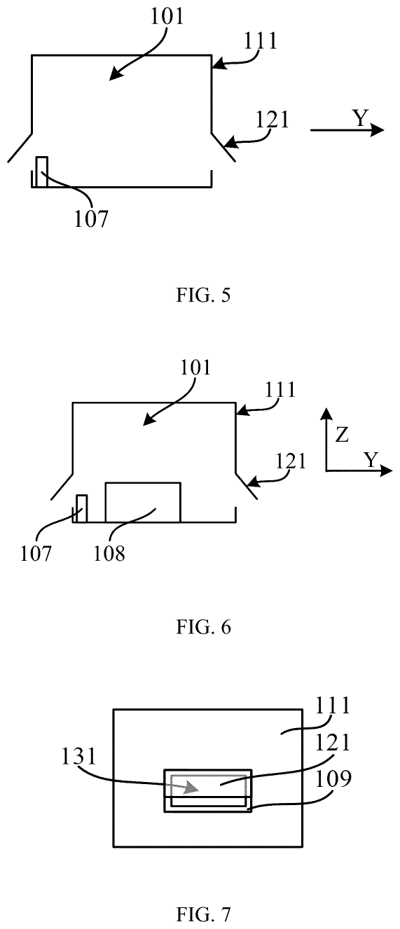

In some embodiments, with reference to FIG. 4 and FIG. 5, FIG. 5 is a schematic partial cross-sectional view of a heat dissipation device according to some embodiments of the present disclosure. The heat dissipation device may further include a heat dissipation unit 107 arranged inside the chamber 101. The controller 103 may be further configured to start the heat dissipation unit 107 such that the heat dissipation unit 107 is in an operating state, in a case where the controller 103 controls the shell 121 to open based on the first detection information (test1), the second detection information (test2), the third detection information (test3), and the fourth detection information (test4).

In this way, not only is heat dissipation achieved through air convection between the chamber 101 and the external environment, but also the heat dissipation unit 107 accelerates the speed of air convection, thereby further improving the heat dissipation efficiency for the components or elements inside the chamber 101. This allows the hot air inside the chamber 101 to be quickly expelled to the outside of the housing 111, and also helps to effectively prevent the formation of condensation inside the chamber 101.

In some embodiments, with reference to FIG. 6, FIG. 6 is another schematic partial cross-sectional view of a heat dissipation device according to some embodiments of the present disclosure. The chamber 101 further includes at least one heat generation unit 108. The heat dissipation unit 107 is disposed in a portion inside the chamber 101 close to the heat generation unit 108.

It is noteworthy that the heat generation unit 108 inside the chamber 101 generates a significant amount of heat, which makes the portion with higher temperature inside the chamber 101 generally coincide with the portion where the heat generation unit 108 is disposed. This is also the main source of temperature rise inside the chamber 101. The heat accumulation in this portion is more severe, and thus quick heat dissipation measures are required. Based on this, designing the heat dissipation unit 107 to be disposed close to the heat generation unit 108 inside the chamber 101 is conducive to achieve quick and specific heat dissipation for the heat generation unit 108 by virtue of the heat dissipation unit 107. This effectively prevents the accumulation of heat in the portion close to the heat generation unit 108, such that the temperature inside the chamber 101 is quickly lowered.

In some examples, the heat generation unit 108 may be an insulated-gate bipolar transistor (IGBT) and/or an inductor.

In some embodiments, the heat dissipation unit 107 may include at least one pair of fans, where the pair of fans includes an intake fan (not illustrated) and an exhaust fan (not illustrated).

It is noteworthy that while the intake fan absorbs cool air from the external environment of the chamber 101, the exhaust fan expels the hot air from inside the chamber 101 to the outside of the chamber 101. This helps to further increase the speed of air convection between the inside and the outside of the chamber 101, such that the heat dissipation efficiency for the components or elements inside the chamber 101 is further improved.

It should be noted that the intake fan and the exhaust fan are arranged in pairs, that is, one intake fan and one exhaust fan form a pair of fans. In practical applications, the number of intake and exhaust fan pairs may be flexibly defined based on the specific heat generation of the components or elements inside the chamber 101.

In some examples, the intake and exhaust fans may be symmetrically placed to promote the formation of air convection between the inside and the outside the chamber 101, which further increases the speed of air convection and improves the heat dissipation efficiency.

In some embodiments, referring to FIG. 3, FIG. 5, or FIG. 6, an overall exterior surface area of the housing 111 is a first area, and an exterior surface area of the shell 121 is a second area, where a ratio of the second area to the first area ranges from 20% to 40%.

It is noteworthy that the shell 121 serves as a component or element that allows air convection between the chamber 101 and the external environment. In a case where the ratio of the second area to the first area is less than 20%, for the entire housing 11, when the shell 121 is opened, an opening formed on the housing 111 for air convection is relatively small. This is unfavorable for quickly expelling the hot air inside the chamber 101 to the external environment, which negatively impacts the heat dissipation performance of the chamber 101. In a case where the ratio of the second area to the first area exceeds 40%, for the entire housing 111, when the shell 121 is opened, an opening formed on the housing 111 for air convection is relatively large. This results in that an excessively large portion of the chamber 101 is directly exposed to the external environment, which reduces the ability to form a protective barrier with the shell 121. As such, significant safety risks are introduced. For instance, where an emergency occurs when the shell 121 is opened, the large surface area of the shell 121 makes it difficult to quickly close the shell 121, and thus the chamber 101 is prevented from returning to a sealed state in time.

Therefore, designing the ratio of the second area to the first area as 20% to 40% is conducive to ensuring that the size of the opening for air convection formed on the housing 111 is appropriate. This design enhances the heat dissipation efficiency of the chamber 101 while reducing the safety risks associated with the chamber 101.

In some embodiments, with reference to FIG. 7, FIG. 7 is a side view of a chamber in a heat dissipation device according to some embodiments of the present disclosure. Openings 131 in one-to-one correspondence with the shells 121 are defined in the housing 111. When the shell 121 is not opened, the shell 121 is in fit with the opening 131. The heat dissipation device 100 may also include a sealing strip 109, arranged around an edge of the opening 131. In practice, the sealing strip 109 may also be arranged around an edge of the shell 121.

It should be noted that in FIG. 7, the sealing strip 109 around the edge of the opening 131 is not illustrated. The shell 121 is illustrated in a perspective view, and the side view in FIG. 7 represents the condition when the shell 121 is opened.

It is noteworthy that because there may be relative movements between the shell 121 and other parts of the housing 111, the shell 121 may be in fit with the opening 131. In a case where the shell 121 is in fit with other parts of the housing 111, extremely small gaps may be defined between the shell 121 and the other parts of the housing 111. A sealing strip 109 is arranged around the edge where the shell 121 and the other parts of the housing 111 are in fit. The sealing strip 109 helps to seal the gaps between the shell 121 and the other parts of the housing 111. This is conducive to further improving the sealing performance of the chamber 101, such that the IP protection rating for the chamber 101 is further enhanced.

In some embodiments, referring to FIG. 3, FIG. 5, or FIG. 6, the housing 111 includes at least two shells 121 spaced apart, and the predetermined environment includes a first-level predetermined environment and a second-level predetermined environment. The controller 103 is further configured to: in a case where it is determined based on the first detection information test1, the second detection information test2, the third detection information test3, and the fourth detection information test4 that the chamber 101 is in the first-level predetermined environment, control N shells to open; or in a case where it is determined based on the first detection information test1, the second detection information test2, the third detection information test3, and the fourth detection information test4 that the chamber 101 is in the second-level predetermined environment, control more than N shells 121 to open, where N is a positive integer greater than or equal to 1.

FIG. 3, FIG. 5, or FIG. 6 illustrates two shells 121 arranged relative to each other along the second direction Y. In practice, a plurality of shells may be spaced apart along the first direction X, as illustrated in FIG. 2. One of the first direction X and the second direction Y is a length direction of the heat dissipation device, and the other of the first direction X and the second direction Y is a width direction of the heat dissipation device.

It should be noted that, compared to the first-level predetermined environment, the second-level predetermined environment may require more frequent opening of the shells 121 for heat dissipation. Based on this logic, the difference between the first-level predetermined environment and the second-level predetermined environment may be defined as a difference in the determination logic for at least one of the first detection information test1, the second detection information test2, the third detection information test3, and the fourth detection information test4. In practice, the differences between the first-level predetermined environment and the second-level predetermined environment may be adjusted based on the specific application environment of the chamber 101, such that the heat dissipation requirements and IP protection rating requirements of the chamber 101 are better accommodated.

In some examples, the difference between the first-level predetermined environment and the second-level predetermined environment may lie in the determination logic for the first detection information test1. For example, in a case where the second detection information test2, the third detection information test3, and the fourth detection information test4 all satisfy the corresponding predetermined conditions, when it is determined, based on the first detection information test1, that the temperature difference between the inside and the outside of the chamber 101 is greater than or equal to 30° C., the chamber 101 is determined to be in the first-level predetermined environment. When it is determined, based on the first detection information test1, that the temperature difference between the inside and the outside of the chamber 101 is greater than or equal to 40° C., the chamber 101 is determined to be in the second-level predetermined environment. In the second-level predetermined environment, since the temperature difference between the interior and the exterior of the chamber 101 is greater, the controller 103 is designed to control a greater number of shells 121, which helps to accelerate the heat dissipation speed of the chamber 101. This, in turn, helps to reduce the duration for which the shells 121 remain open, such that the time during which the chamber 101 is exposed to the external environment is minimized. In this way, the heat dissipation efficiency is improved, while the IP protection rating for the chamber 101 is enhanced.

It should be noted that the above example only illustrates the difference between the first-level predetermined environment and the second-level predetermined environment based on the determination logic of the first detection information test1. The judgment logic for the second detection information test2, the third detection information test3, and the fourth detection information test4 may also cause differences between the first-level predetermined environment and the second-level predetermined environments. The differences between these environments may be flexibly adjusted based on the actual application scenario, which is not elaborated herein any further.

In one example, the housing 111 may include two spaced-apart shells 121, and the two shells 121 are respectively designed on opposite sides of the housing 111. For instance, the two shells 121 may be designed on left and right sides or on front and back sides of the housing 111. This design facilitates the formation of air convection when both shells 121 are opened, such that the heat dissipation performance of the chamber 101 is further enhanced.

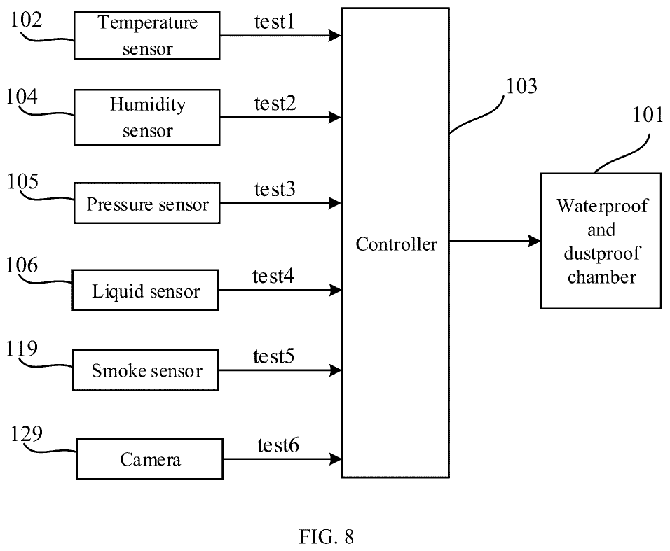

In some embodiments, referring to FIG. 8, which is another functional block diagram of a heat dissipation device 100 according to some embodiments of the present disclosure. The heat dissipation device 100 may further include a smoke sensor 119, configured to detect smoke in an external environment outside the chamber 101, and provide a detection result as fifth detection information test5 to the controller 106. The controller 103 is further configured to determine, based on the fifth detection information test5, whether smoke is present outside the chamber 101. In response to determining that smoke is present outside the chamber 101, the controller 103 controls the shell 121 to close; and in response to determining that smoke is not present outside the chamber 101, the controller determines whether the chamber 101 is in the predetermined environment based on the first detection information test1, the second detection information test2, the third detection information test3, and the fourth detection information test4.

It should be noted that in a case where the controller 103 determines, based on the fifth detection information test5, that smoke is present in the external environment of the chamber 101, this indicates the presence of a fire or a hazardous environment. In such a case, even though the controller 103 determines, based on the first detection information test1, the second detection information test2, the third detection information test3, and fourth detection information test4, that the chamber 101 is in the predetermined environment, the shell 121 should not be opened. Therefore, designing the smoke sensor 119 to detect smoke and the controller 103 to determine, based on the fifth detection information test5, whether there is smoke outside the chamber 101 is conducive to further improving the IP protection rating for the chamber 101. This prevents accidental opening of the shell 121, and thus avoid potential damage to the components or elements inside the chamber 101. In other words, this design allows the controller 103 to more accurately analyze whether the environment of the chamber 101 is suitable for opening the shell 121 to quickly dissipate heat.

In some embodiments, still referring to FIG. 8, the heat dissipation device 100 may further include a camera 129, configured to capture an image of an external environment outside the chamber 101, and provide an imaging result as sixth detection information test6 to the controller 103. The controller 103 is further configured to determine, based on the sixth detection information test6, whether a living organism is present outside the chamber 101. In response to determining that a living organism is present outside the chamber 101, the controller 103 controls the shell 121 to close; and in response to determining that no living organism is present outside the chamber 101, the controller 103 determines whether the chamber 101 is in the predetermined environment based on the first detection information test1, the second detection information test2, the third detection information test3, and the fourth detection information test4.

It should be noted that in a case where the controller 103 determines, based on the sixth detection information test6, that a living organism is present in the external environment of the chamber 101, there is a risk that the living organism enters the chamber and causes damage to the components or elements inside the chamber 101. For example, the living organism detected by the camera 129 may be a small animal like a cockroach or an ant, which might move into the chamber 101 and damage the components or element thereinside, such as disturbing cables in the components or elements. In such a case, even though the controller 103 determines, based on the first detection information test1, the second detection information test2, the third detection information test3, and fourth detection information test4, that the chamber 101 is in the predetermined environment, the shell 121 should not be opened. Therefore, designing the camera 129 to detect smoke and the controller 103 to determine, based on the sixth detection information test6, whether there is a living organism outside the chamber 101 is conducive to further improving the IP protection rating for the chamber 101. This prevents accidental opening of the shell 121, and thus avoid potential damage to the components or elements inside the chamber 101. In other words, this design allows the controller 103 to more accurately analyze whether the environment of the chamber 101 is suitable for opening the shell 121 to quickly dissipate heat.

In summary, an shell 121 is designed on a housing 111 of a chamber 101, and additionally, a temperature sensor 102, a humidity sensor 104, a pressure sensor 105, and a liquid sensor 106 are incorporated to comprehensively monitor an environment of the chamber 101 from at least four aspects. Furthermore, a controller 103 is then designed to comprehensively consider various detection information data from these sensors to determine whether the chamber 101 is in a predetermined environment. Based on coordination of the temperature sensor 102, the humidity sensor 104, the pressure sensor 105, the liquid sensor 106, and the controller 103, the controller 103 may control the shell 121 to open only in a case where the chamber 101 is in the predetermined environment. This allows the chamber 101 to achieve rapid heat dissipation through inside-outside air convection via the shell 121. Furthermore, in a case where the chamber 101 is not in the predetermined environment, the controller 103 controls the shell 121 to close. This ensures that the chamber 101 remains in a sealed state to maintain a high IP protection rating.

Some other embodiments of the present disclosure further provide a heat dissipation method. The heat dissipation method is used to control the heat dissipation device according to the above embodiments to implement heat dissipation. The heat dissipation method according to the embodiments of the present disclosure is described in detail with reference to the accompanying drawings. It should be noted that the parts that are the same as or correspond to the above embodiments are not described herein any further.

Referring to FIG. 3 to FIG. 4, a heat dissipation method includes: providing a temperature sensor 102, a humidity sensor 104, a pressure sensor 105, a liquid sensor 106, and a controller; detecting a temperature difference between interior and exterior of a chamber 101, and feeding back a detection result as first detection information test1 to the controller 103; detecting a humidity outside the chamber 101, and feeding back a detection result as second detection information test2 to the controller 103; detecting a pressure on the chamber 101, and feeding back a detection result as third detection information test3 to the controller 103; detecting a height of liquid outside the chamber 101 with a bottom surface of the chamber 101 as a reference, and feeding back a detection result as fourth detection information test4 to the controller 103; providing the chamber 101 formed a housing 111, and designing at least one shell 121 on the housing 111; receiving the first detection information test1, the second detection information test2, the third detection information test3, and the fourth detection information test4 by virtue of the controller 103, and determining whether the chamber 101 is in a predetermined environment based on the first detection information test1, the second detection information test2, the third detection information test3, and the fourth detection information test4; and in response to determining that the chamber 101 is in the predetermined environment, controlling, by virtue of the controller 103 the shell 121 to open to control the chamber 101 to carry out inside-outside air convection through the shell that is opened; and in response to determining that the chamber 101 is not in the predetermined environment, controlling, by virtue of the controller 103, the shell 121 to close such that the chamber 101 is in a sealed state.

In some embodiments, determining whether the chamber is in the predetermined environment based on the first detection information test1, the second detection information test2, the third detection information test3, and the fourth detection information test4 includes: determining, based on the first detection information test1, whether the chamber 101 satisfies a first predetermined condition, determining, based on the second detection information test2, whether the chamber 101 satisfies a second predetermined condition, determining, based on the third detection information test3, whether the chamber 101 satisfies a third predetermined condition, and determining, based on the fourth detection information test4, whether the chamber 101 satisfies a fourth predetermined condition; and in response to determining that the chamber 101 simultaneously satisfies the first predetermined condition, the second predetermined condition, the third predetermined condition, and the fourth predetermined condition, determining that the chamber 101 is in the predetermined environment; and in response to determining that the chamber 101 does not satisfy at least one of the first predetermined condition, the second predetermined condition, the third predetermined condition, or the fourth predetermined condition, determining that the chamber 101 is not in the predetermined environment. The first predetermined condition is that the temperature difference between the interior and the exterior of the chamber 101 is greater than or equal to a first predetermined value, the second predetermined condition is that the humidity outside the chamber 101 is less than a second predetermined value, the third predetermined condition is that the pressure applied by the external environment on the chamber 101 is less than a third predetermined value, and the fourth predetermined condition is that the height of liquid outside the chamber 101 is lower than the bottom surface of the chamber 101.

In some embodiments, as illustrated in FIG. 8, the heat dissipation method further includes: providing a smoke sensor 119, detecting smoke in the external environment of the chamber 101 by virtue of the smoke sensor 119, and feeding back a detection result as fifth detection information test5 to the controller 103; and receiving the fifth detection information test5 by virtue of the controller 103 and determining, based on the fifth detection information test5, whether smoke is present in the external environment of the chamber 101, prior to receiving the first detection information test1, the second detection information test2, the third detection information test3, and the fourth detection information test4 by virtue of the controller 103 and determining, based on the first detection information test1, the second detection information test2, the third detection information test3, and the fourth detection information test4, whether the chamber 101 is in the predetermined environment.

In some embodiments, as illustrated in FIG. 8, the heat dissipation method further includes: providing a camera 129, imaging the external environment of the chamber 101 by virtue of the camera 129, and feeding back an imaging result as sixth detection information test6 to the controller 103; and receiving the fifth detection information test5 by virtue of the controller 103 and determining, based on the fifth detection information test5, whether a living organism is present in the external environment of the chamber 101, prior to receiving the first detection information test1, the second detection information test2, the third detection information test3, and the fourth detection information test4 by virtue of the controller 103 and determining, based on the first detection information test1, the second detection information test2, the third detection information test3, and the fourth detection information test4, whether the chamber 101 is in the predetermined environment.

Some other embodiments of the present disclosure further provide an energy storage system. The energy storage system includes the heat dissipation device according to the above embodiments. The energy storage system according to the embodiments of the present disclosure is described in detail with reference to the accompanying drawings. It should be noted that the parts that are the same as or correspond to the above embodiments are not described herein any further.

With reference to FIG. 1 or FIG. 2, the energy storage system includes the heat dissipation device 100 according to the above embodiments. Based on the design of the shell 121 on the housing 111 of the heat dissipation device 100, and the cooperation of the temperature sensor 102, the humidity sensor 104, the pressure sensor 105, the liquid sensor 106, and the controller 103, the heat dissipation efficiency of the chamber 101 is improved, and the IP protection rating for the chamber 101 is enhanced, such that the service life of the energy storage system is extended.

Persons of ordinary skill in the art shall understand that the above embodiments are merely specific and exemplary embodiments for practicing the present disclosure, and in practice, various modifications may be made to these embodiments in terms of form and detail, without departing from the spirit and scope of the embodiments of the present disclosure. Variations and modifications may be made by one skilled in the art without departing from the spirit and scope of the embodiments of the present disclosure. Accordingly, the protection scope of the embodiments of the present disclosure is subject to the appended claims.

What is claimed is:

1. A heat dissipation device applicable to a high-power driver, comprising:
a controller;
a chamber formed by a housing, wherein the housing comprises at least one shell operable to be opened to allow air convection between an interior and an exterior of the chamber, and wherein the chamber is configured to receive the high-power driver and is waterproof and dustproof, the high-power driver including an inverter or a converter;
a temperature sensor, configured to detect a temperature difference between the interior and the exterior of the chamber, and to provide first detection information to the controller based on detected temperature difference;
a humidity sensor, configured to detect a humidity outside the chamber, and to provide second detection information to the controller based on detected humility difference;
a pressure sensor, configured to detect a pressure applied by an external environment on the chamber, and to provide third detection information to the controller based on detected pressure;
a liquid sensor, configured to detect a height of a liquid outside the chamber with reference to a bottom surface of the chamber, and to provide fourth detection information to the controller based on detected height of the liquid;
wherein the controller is configured to receive the first detection information, the second detection information, the third detection information, and the fourth detection information, and to determine whether the chamber is in a predetermined environment based on the first detection information, the second detection information, the third detection information, and the fourth detection information;
wherein, in response to determining that the chamber is in the predetermined environment, the controller is configured to cause the shell to open; and in response to determining that the chamber is not in the predetermined environment, the controller is configured to cause the shell to close such that the chamber is sealed.

2. The heat dissipation device according to claim 1, wherein determining whether the chamber is in the predetermined environment based on the first detection information, the second detection information, the third detection information, and the fourth detection information comprises:
determining, based on the first detection information, whether the chamber satisfies a first predetermined condition, determining, based on the second detection information, whether the chamber satisfies a second predetermined condition, determining, based on the third detection information, whether the chamber satisfies a third predetermined condition, and determining, based on the fourth detection information, whether the chamber satisfies a fourth predetermined condition; and
in response to determining that the chamber simultaneously satisfies the first predetermined condition, the second predetermined condition, the third predetermined condition, and the fourth predetermined condition, determining that the chamber is in the predetermined environment; and
in response to determining that the chamber does not satisfy at least one of the first predetermined condition, the second predetermined condition, the third predetermined condition, or the fourth predetermined condition, determining that the chamber is not in the predetermined environment;
wherein the first predetermined condition is that the temperature difference between the interior and the exterior of the chamber is greater than or equal to a first predetermined value, the second predetermined condition is that the humidity outside the chamber is less than a second predetermined value, the third predetermined condition is that the external pressure applied by the external environment on the chamber is less than a third predetermined value, and the fourth predetermined condition is that the height of liquid outside the chamber is lower than the bottom surface of the chamber.

3. The heat dissipation device according to claim 2, wherein the first predetermined value ranges from 20°C to 40°C; and/or, the second predetermined value ranges from 70% to 80%; and/or, the third predetermined value ranges from 0.8 MPa to 1.2 MPa.

4. The heat dissipation device according to claim 1, further comprising: a heat dissipation unit, arranged inside the chamber;
wherein the controller is further configured to, in a case where the shell is controlled to open based on the first detection information, the second detection information, the third detection information, and the fourth detection information, activate the heat dissipation unit, such that the heat dissipation unit is in an operating state.

5. The heat dissipation device according to claim 2, further comprising: a heat dissipation unit, arranged inside the chamber;
wherein the controller is further configured to, in a case where the shell is controlled to open based on the first detection information, the second detection information, the third detection information, and the fourth detection information, activate the heat dissipation unit, such that the heat dissipation unit is in an operating state.

6. The heat dissipation device according to claim 3, further comprising: a heat dissipation unit, arranged inside the chamber;
wherein the controller is further configured to, in a case where the shell is controlled to open based on the first detection information, the second detection information, the third detection information, and the fourth detection information, activate the heat dissipation unit, such that the heat dissipation unit is in an operating state.

7. The heat dissipation device according to claim 4, wherein the chamber further comprises at least one heat generation unit, and the heat dissipation unit is disposed in a portion of the chamber close to the heat generation unit.

8. The heat dissipation device according to claim 4, wherein the heat dissipation unit comprises at least one pair of fans, wherein the pair of fans includes an intake fan and an exhaust fan.

9. The heat dissipation device according to claim 1, wherein an overall exterior surface area of the housing is a first area, and an exterior surface area of the shell is a second area, a ratio of the second area to the first area ranging from 20% to 40%.

10. The heat dissipation device according to claim 2, wherein an overall exterior surface area of the housing is a first area, and an exterior surface area of the shell is a second area, a ratio of the second area to the first area ranging from 20% to 40%.

11. The heat dissipation device according to claim 3, wherein an overall exterior surface area of the housing is a first area, and an exterior surface area of the shell is a second area, a ratio of the second area to the first area ranging from 20% to 40%.

12. The heat dissipation device according to claim 1, wherein the housing comprises at least two shells spaced apart, and the predetermined environment comprises a first-level predetermined environment and a second-level predetermined environment; and
the controller is further configured to: in a case where it is determined based on the first detection information, the second detection information, the third detection information, and the fourth detection information that the chamber is in the first-level predetermined environment, control N shells to open; or in a case where it is determined based on the first detection information, the second detection information, the third detection information, and the fourth detection information that the chamber is in the second-level predetermined environment, control more than N shells to open, wherein N is a positive integer greater than or equal to 1.

13. The heat dissipation device according to claim 2, wherein the housing comprises at least two shells spaced apart, and the predetermined environment comprises a first-level predetermined environment and a second-level predetermined environment; and
the controller is further configured to: in a case where it is determined based on the first detection information, the second detection information, the third detection information, and the fourth detection information that the chamber is in the first-level predetermined environment, control N shells to open; or in a case where it is determined based on the first detection information, the second detection information, the third detection information, and the fourth detection information that the chamber is in the second-level predetermined environment, control more than N shells to open, wherein N is a positive integer greater than or equal to 1.

14. The heat dissipation device according to claim 3, wherein the housing comprises at least two shells spaced apart, and the predetermined environment comprises a first-level predetermined environment and a second-level predetermined environment; and
the controller is further configured to: in a case where it is determined based on the first detection information, the second detection information, the third detection information, and the fourth detection information that the chamber is in the first-level predetermined environment, control N shells to open; or in a case where it is determined based on the first detection information, the second detection information, the third detection information, and the fourth detection information that the chamber is in the second-level predetermined environment, control more than N shells to open, wherein N is a positive integer greater than or equal to 1.

15. The heat dissipation device according to claim 1, further comprising: a smoke sensor, configured to detect smoke in an external environment outside the chamber, and provide a detection result as fifth detection information to the controller;
wherein the controller is further configured to determine, based on the fifth detection information, whether smoke is present outside the chamber; wherein in response to determining that smoke is present outside the chamber, the controller controls the shell to close; and in response to determining that smoke is not present outside the chamber, the controller determines whether the chamber is in the predetermined environment based on the first detection information, the second detection information, the third detection information, and the fourth detection information.

16. The heat dissipation device according to claim 2, further comprising: a smoke sensor, configured to detect smoke in an external environment outside the chamber, and provide a detection result as fifth detection information to the controller;
wherein the controller is further configured to determine, based on the fifth detection information, whether smoke is present outside the chamber; wherein in response to determining that smoke is present outside the chamber, the controller controls the shell to close; and in response to determining that smoke is not present outside the chamber, the controller determines whether the chamber is in the predetermined environment based on the first detection information, the second detection information, the third detection information, and the fourth detection information.

17. The heat dissipation device according to claim 3, further comprising: a smoke sensor, configured to detect smoke in an external environment outside the chamber, and provide a detection result as fifth detection information to the controller;
wherein the controller is further configured to determine, based on the fifth detection information, whether smoke is present outside the chamber; wherein in response to determining that smoke is present outside the chamber, the controller controls the shell to close; and in response to determining that smoke is not present outside the chamber, the controller determines whether the chamber is in the predetermined environment based on the first detection information, the second detection information, the third detection information, and the fourth detection information.

18. The heat dissipation device according to claim 1, further comprising: a camera, configured to capture an image of an external environment outside the chamber, and provide an imaging result as sixth detection information to the controller;
wherein the controller is further configured to determine, based on the sixth detection information, whether a living organism is present outside the chamber; wherein in response to determining that a living organism is present outside the chamber, the controller controls the shell to close; and in response to determining that no living organism is present outside the chamber, the controller determines whether the chamber is in the predetermined environment based on the first detection information, the second detection information, the third detection information, and the fourth detection information.

19. The heat dissipation device according to claim 2, further comprising: a camera, configured to capture an image of an external environment outside the chamber, and provide an imaging result as sixth detection information to the controller;
wherein the controller is further configured to determine, based on the sixth detection information, whether a living organism is present outside the chamber; wherein in response to determining that a living organism is present outside the chamber, the controller controls the shell to close; and in response to determining that no living organism is present outside the chamber, the controller determines whether the chamber is in the predetermined environment based on the first detection information, the second detection information, the third detection information, and the fourth detection information.

20. The heat dissipation device according to claim 3, further comprising: a camera, configured to capture an image of an external environment outside the chamber, and provide an imaging result as sixth detection information to the controller;
wherein the controller is further configured to determine, based on the sixth detection information, whether a living organism is present outside the chamber; wherein in response to determining that a living organism is present outside the chamber, the controller controls the shell to close; and in response to determining that no living organism is present outside the chamber, the controller determines whether the chamber is in the predetermined environment based on the first detection information, the second detection information, the third detection information, and the fourth detection information.
